(19) United States
(12) Patent Application Publication
(10) Pub. No.: US 2016/0148693 A1
(43) Pub. Date: May 26, 2016

(54) SEMICONDUCTOR DEVICE

(71) Applicant: SK hynix Inc., Icheon-si Gyeonggi-do (KR)

(72) Inventor: Hee Youl LEE, Icheon-si Gyeonggi-do (KR)

(21) Appl. No.: 14/709,079

(22) Filed: May 11, 2015

(30) Foreign Application Priority Data
Nov. 24, 2014 (KR) 10-2014-0164579

(51) Int. Cl. G11C 16/10; G11C 16/34

(52) U.S. Cl. CPC G11C 16/10; G11C 16/3459

(57) ABSTRACT

A semiconductor device is provided. The semiconductor device may include a memory block including memory cells, the memory cells connected to a word line. The semiconductor device may include an operation circuit configured to apply a preprogram pulse to the word line, and to perform a main program loop including a main program operation and a program verification operation to store data in the memory cells connected to the word line. The preprogram pulse may have a higher voltage level than a first main program pulse applied to the word line when the main program operation is first performed.

### CROSS-REFERENCE TO RELATED APPLICATION

The present application claims priority to Korean patent application number 10-2014-0164579 filed on Nov. 24, 2014, in the Korean Intellectual Property Office, the entire disclosure of which is incorporated by reference herein.

### BACKGROUND

1. Technical Field

Various embodiments generally relate to a semiconductor device, and more particularly, to a semiconductor device including a memory cell.

2. Related Art

To store data in a semiconductor device including a flash memory cell a program operation is performed by the semiconductor device. In the program operation, a threshold voltage of the memory cell increases in relation to the time for a program voltage to be applied to the memory cell. The program operating time and the threshold voltage distribution of memory cells are determined according to the method relating to applying the program voltage. The program operating time and the threshold voltage distribution of memory cells are determined when the threshold voltage distribution widens. Thus, the operating time and the operation characteristics of the semiconductor device may be degraded.

### SUMMARY

In an embodiment, a semiconductor device may include a memory block including memory cells, the memory cells connected to a word line. The semiconductor device may include an operation circuit configured to apply a preprogram pulse to the word line, and to perform a main program loop including a main program operation and a program verification operation to store data in the memory cells connected to the word line. The preprogram pulse may have a higher voltage level than a first main program pulse applied to the word line when the main program operation is first performed.

In an embodiment, a semiconductor device may include a memory block including memory cells, the memory cells connected to a word line. The semiconductor device may include an operation circuit configured to perform a preprogram operation and a preprogram verification operation, and to perform a main program loop including a main program operation and a program verification operation to store data in the memory cells connected to the word line. The preprogram pulse of the preprogram operation may have a higher voltage level than a first main program pulse of the main program loop applied to the word line.

### BRIEF DESCRIPTION OF THE DRAWINGS

FIG. 1 is a block diagram illustrating a representation of an example of a semiconductor device according to an embodiment.

FIGS. 2A and 2B are views illustrating a representation of an example of a memory array according to an embodiment.

FIGS. 3A to 3E are views illustrating a representation of an example of a memory array according to an embodiment.

FIGS. 4A to 4F are waveforms illustrating a representation of an example of a method of operating a semiconductor device according to an embodiment.

FIGS. 5A to 5F are waveforms illustrating a representation of an example of a method of operating a semiconductor device according to an embodiment.

FIG. 6 is a block diagram illustrating a representation of an example of a memory system according to an embodiment.

FIG. 7 is a block diagram illustrating a representation of an example of a fusion memory device or a fusion memory system configured to perform a program operation according to the above-mentioned embodiments.

FIG. 8 is a block diagram illustrating a representation of an example of a computing system including a flash memory device according to an embodiment.

### DETAILED DESCRIPTION

Hereinafter, various examples of embodiments will now be described with reference to the accompanying drawings to clarify aspects, features, and advantages of the application. The embodiments may, however, be embodied in many different forms and should not be construed as being limited to the embodiments set forth herein. Rather, these embodiments are provided so that this disclosure will be through and complete, and will fully convey the concepts to those of ordinary skill in the art.

Various embodiments may be directed to a semiconductor device capable of improving an operating time and operation characteristics.

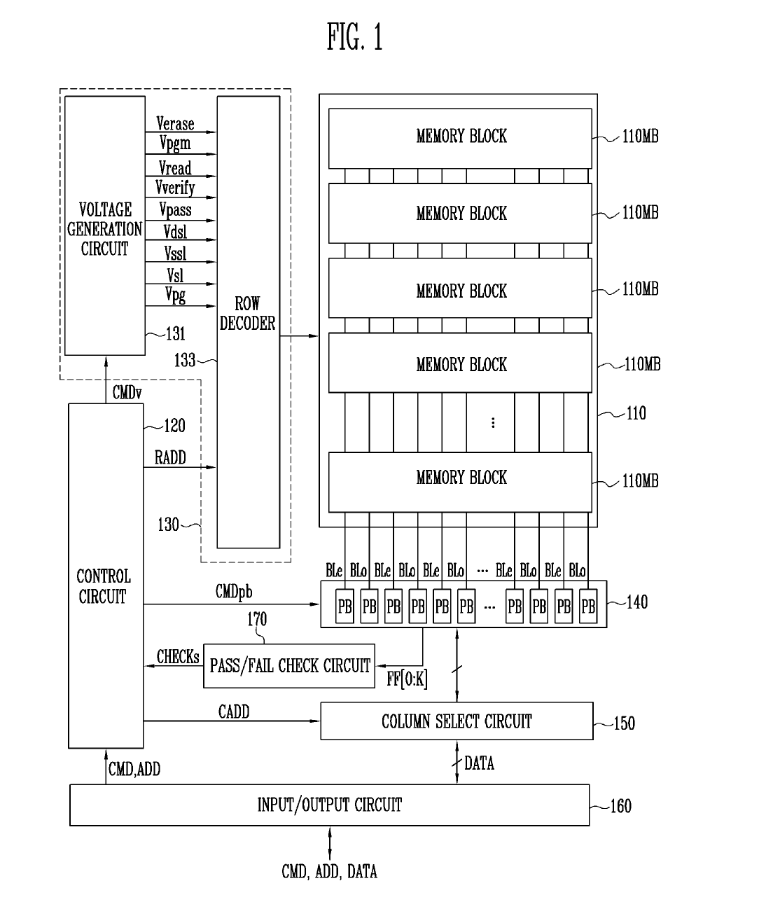

FIG. 1 is a block diagram illustrating a representation of an example of a semiconductor device according to an embodiment.

Referring to FIG. 1, the semiconductor device may include a memory array 110 and operation circuits 120 to 170. The memory array 110 includes a plurality of memory blocks (110MB). Each of the memory blocks includes a plurality of memory strings. Each of the memory strings includes a plurality of memory cells. In a flash memory device, a memory block may include flash memory cells.

The memory block may include memory strings connected to bit lines, respectively, and connected to a common source line in parallel. The memory strings may be formed in a 2-dimensional structure or a 3-dimensional structure on a semiconductor substrate. A structure of the memory block will be explained below.

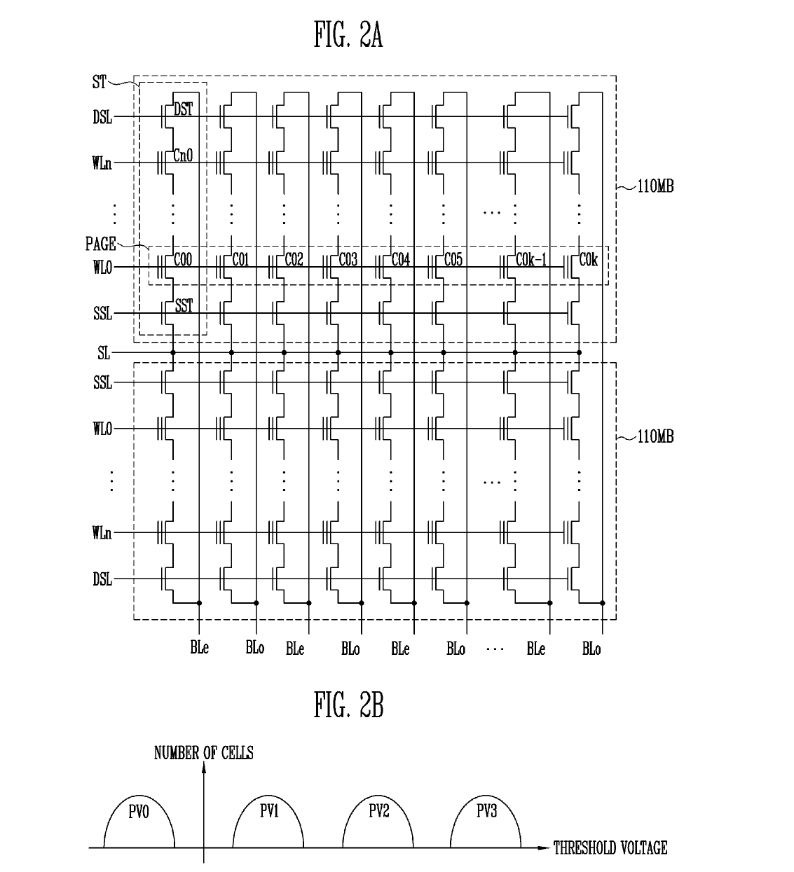

FIGS. 2A and 2B are views illustrating a representation of an example of a memory array according to an embodiment.

Referring to FIG. 2A, each of the memory blocks may include the plurality of memory strings ST connected between the bit lines BLe and BLo, and the common source line SL. The memory strings ST are connected to the corresponding bit lines BLe and BLo, respectively. The memory strings ST are commonly connected to the common source line SL. Each of the memory strings ST includes a source select transistor SST. The source of the source select transistor SST is connected to the common source line SL. Each of the memory strings ST includes a cell string including a plurality of memory cells C00 to Cn0 are connected in series, and a drain select transistor DST. The drain of the drain select transistor DST is connected to the bit line BLe or BLo. The memory cells C00 to Cn0 included in the cell string are connected in series between the select transistors SST and DST. A gate of the source select transistor SST is connected to a source select line SSL, gates of the memory cells C00 to Cn0 are connected to word lines WL0 to WLn, respectively, and a gate of the drain select transistor DST is connected to a drain select line DSL.

The drain select transistor DST controls the connection or disconnection between the cell string and the bit lines. The source select transistor SST controls the connection or disconnection between the cell string and the common source line SL.

In a NAND flash memory device, memory cells included in a memory cell block may be classified based on a physical page basis or a logical page basis. For example, memory cells C00 to C0k connected to one word line (for example, WL0) may be included in one physical page PAGE. For example, even memory cells (for example, C00, C02, C04, and C0k−1) connected to one word line (for example, WL0) may be included in an even page, and odd memory cells (for example, C01, C03, C05, and C0k) connected to the one word line may be included in an odd page. These pages (or, the even page and the odd page) may be the basic units of a program operation or a read operation.

Referring to FIG. 2B, when a program loop for storing data in the memory cells C00 to C0k of the selected word line (for example, WL0) is finished, threshold voltages of the memory cells C00 to C0k are distributed to the erase level PV0 and the program levels PV1 to PV3 based on the stored data.

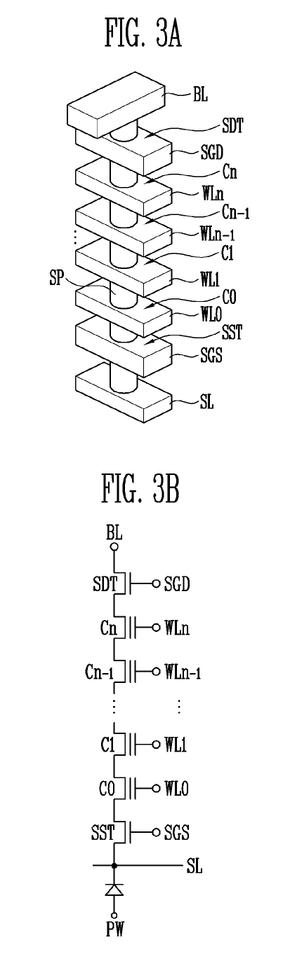

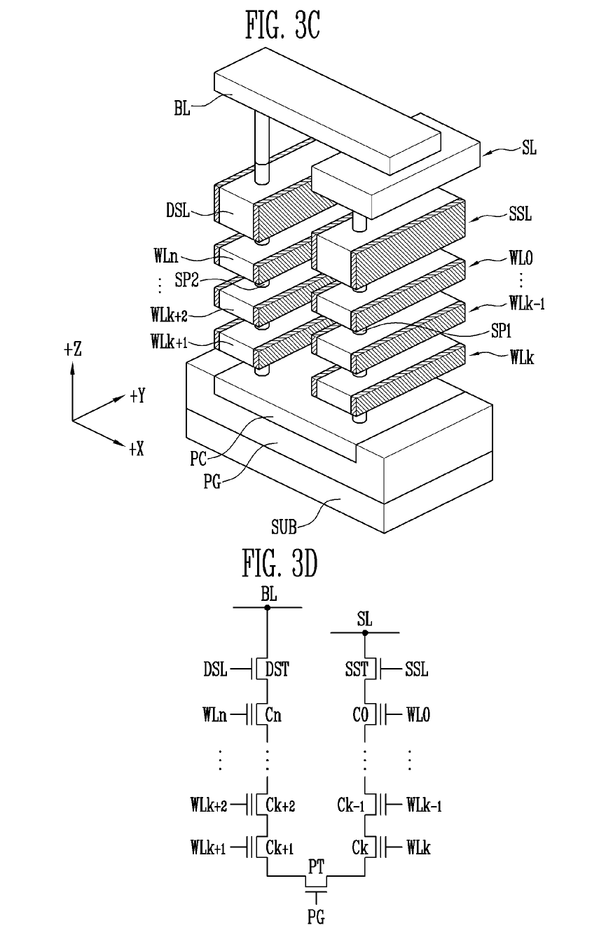

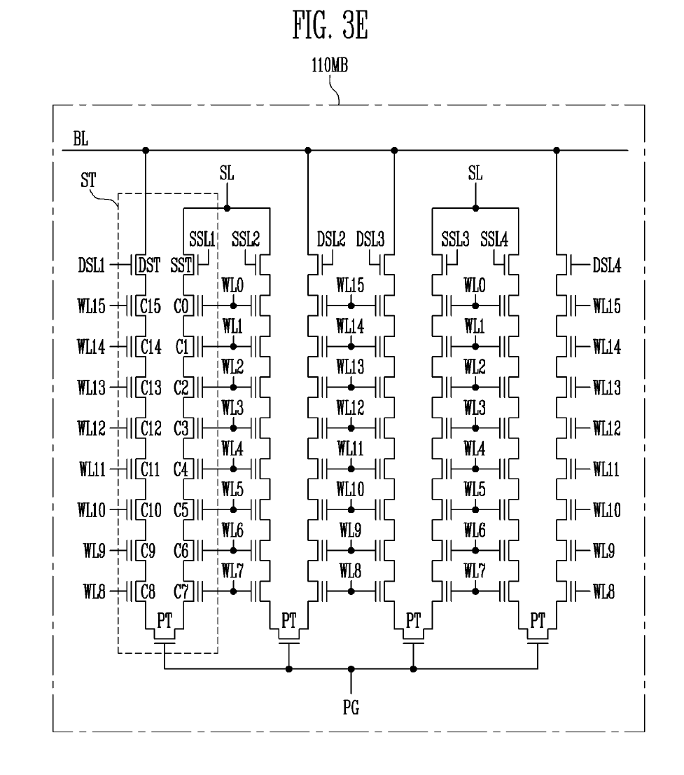

FIGS. 3A to 3E are views illustrating a representation of an example of a memory array according to an embodiment.

Referring to FIGS. 3A and 3B, a common source line SL is formed on a semiconductor substrate SUB on which a P-well PW is formed. A vertical channel layer SP is formed on the common source line SL. An upper portion of the vertical channel layer SP is connected to a bit line BL. The vertical channel layer SP may be formed of polysilicon. A plurality of conductive layers SGS, WL0 to WLn, and SGD are formed to surround the vertical channel layer SP at different heights of the vertical channel layer SP. A multi-layered layer (not illustrated) including a charge trap layer is formed on a surface of the vertical channel layer SP, and a multi-layered layer is also interposed between the vertical channel layer SP and the conductive layers SGS, WL0 to WLn, and SGD.

The lowermost conductive layer serves as a source select line (or a first select line) SGS, and the uppermost conductive layer serves as a drain select line (or a second select line) SGD. The conductive layers between the select lines SGS and SGD serve as word lines WL0 to WLn. The conductive layers SGS, WL0 to WLn, and SGD are formed as multiple layers on the semiconductor substrate, and the vertical channel layer SP passing through the conductive layers SGS, WL0 to WLn, and SGD is vertically connected between the bit line BL and the common source line SL formed on the semiconductor substrate.

A drain select transistor (or the second select transistor) SDT is formed at a portion where the uppermost conductive layer SGD surrounds the vertical channel layer SP. A source select transistor (or the first select transistor) SST is formed at a portion where the lowermost conductive layer SGS surrounds the vertical channel layer SP. Memory cells C0 to Cn are formed at portions where the intermediate conductive layers WL0 to WLn surround the vertical channel layer SP.

According to the above-mentioned structures, the memory string may include the source select transistor SST, the memory cells C0 to Cn, and the drain select transistor SDT, which are perpendicularly or substantially perpendicularly connected to the substrate between the common source line SL and the bit line BL. The source select transistor SST electrically connects the memory cells C0 to Cn, to the common source line SL based on a first select signal applied to the first select line SGS. The drain select transistor SDT electrically connects the memory cells C0 to Cn, to the bit line BL based on a second select signal applied to the second select line SGD.

Referring to FIGS. 3C and 3D, a pipe gate PG, the pipe gate PG including a recessed part, is formed on a semiconductor substrate SUB. A pipe channel layer PC is formed in the recessed part of the pipe gate PG. A plurality of vertical channel layers SP1 and SP2 are formed on the pipe channel layer PC. An upper portion of the first vertical channel layer SP1 among the pair of the vertical channel layers SP1 and SP2 is connected to a common source line SL. An upper portion of the second vertical channel layer SP2 is connected to a bit line BL. The vertical channel layers SP1 and SP2 may be formed of polysilicon.

A plurality of conductive layers DSL and WLn to WLk+1 are formed to surround the second vertical channel layer SP2 at different heights of the second vertical channel layer SP2. A plurality of conductive layers SSL and WL0 to WLk are formed to surround the first vertical channel layer SP1 at different heights of the first vertical channel layer SP1. A multi-layered layer (not illustrated) including a charge trap layer is formed on surfaces of the vertical channel layers SP1 and SP2 and a surface of the pipe channel layer PC. A multi-layered layer (not illustrated) is also interposed between the vertical channel layers SP1 and SP2 and the conductive layers DSL, WLn to WLk+1, SSL, WL0 to WLk and between the pipe channel layer PC and the pipe gate PG.

The uppermost conductive layer surrounding the second vertical channel layer SP2 may serve as a drain select line DSL. The conductive layers under the drain select line DSL may serve as word lines WLn to WLk+1. The uppermost conductive layer surrounding the first vertical channel layer SP1 may serve as a source select line SSL. The conductive layers under the source select line SSL may serve as word lines WL0 to WLk. Some of the conductive layers used as the word lines may serve as dummy word lines (not illustrated).

First conductive layers SSL and WL0 to WLk and second conductive layers DSL and WLn to WLk+1 are each stacked on different areas of the semiconductor substrate. The first vertical channel layer SP1 passing through the first conductive layers SSL and WL0 to WLk is vertically connected between the common source line SL and the pipe channel layer PC. The second vertical channel layer SP2 passing through the second conductive layers DSL and WLn to WLk+1 is vertically connected between the bit line BL and the pipe channel layer PC.

A drain select transistor DST is formed at a portion where the drain select line DSL surrounds the second vertical channel layer SP2. Main cell transistors Cn to Ck+1 are each formed at portions where the word lines WLn to WLk+1 surround the second vertical channel layer SP2.

A source select transistor SST is formed at a portion where the source select line SSL surrounds the first vertical channel layer SP1. The main cell transistors C0 to Ck are each formed at portions where the word lines WL0 to WLk surround the first vertical channel layer SP1.

According to the above-mentioned structures, the memory string may include the drain select transistor DST and the main cell transistors Cn to Ck+1, perpendicularly or substantially perpendicularly connected to the substrate SUB between the bit line BL and the pipe channel layer PC, and the source select transistor SST and the main cell transistors C0 to Ck, perpendicularly or substantially perpendicularly connected to the substrate SUB between the common source line SL and the pipe channel layer PC. In the above-mentioned structures, a dummy cell transistor (not illustrated) may be further connected between the select transistor DST (or SST) and the main cell transistor Cn (or C0), and a dummy cell transistor (not illustrated) may be further connected between the main cell transistor Ck+1 (or Ck) and a pipe transistor PT.

The source select transistor SST and the main cell transistors C0 to Ck, connected between the common source line SL and the pipe transistor PT, may be included in the first vertical memory string. The drain select transistor DST and the main cell transistors Cn to Ck+1, connected between the bit line BL and the pipe transistor PT, may be included in the second vertical memory string.

Referring to FIG. 3E, the memory block 110MB includes a plurality of memory strings ST connected to bit lines. In a P-BiCS structure, each of the memory strings ST includes a first vertical memory string SST and C0 to C7 vertically connected between the common source line SL and the pipe transistor PT of a substrate, and a second vertical memory string C8 to C15 and DST vertically connected between the bit line BL and the pipe transistor PT of the substrate. The first vertical memory string SST and C0 to C7 includes a source select transistor SST and memory cells C0 to C7. The source select transistor SST is controlled by a voltage applied to the source select line SSL1. The memory cells C0 to C7 are controlled by voltages applied to the stacked word lines WL0 to WL7. The second vertical memory string C8 to C15 and DST includes a drain select transistor DST and memory cells C8 to C15. The drain select transistor DST is controlled by a voltage applied to the drain select line DSL1. The memory cells C8 to C15 are controlled by voltages applied to the stacked word lines WL8 to WL15.

When the memory block 110MB is selected, the pipe transistor PT connected between a pair of memory cells C7 and C8 disposed at a center of the memory string in the P-BiCS structure performs an operation to electrically connect the channel layers of the first vertical memory string SST and C0 to C7 included in the selected memory block 110MB to the channel layers of the second vertical memory string C8 to C15, and DST.

In a memory block with the 2-dimensional structure, one memory string is connected to every bit line and the drain select transistors of the memory block are simultaneously controlled by one drain select line, however, in the memory block 110MB with the 3-dimensional structure, a plurality of the memory strings ST are commonly connected to each bit line BL. In the same memory block 110MB, the number of the memory strings ST commonly connected to one bit line BL and controlled by the same word lines may be changed based on a design.

As the plurality of memory strings are connected to one bit line BL in parallel, the drain select transistors DST are independently controlled by select voltages applied to the drain select lines DSL1 to DSL4 to selectively connect one bit line BL to the memory strings ST.

The memory cells C0 to C7 of the first vertical memory string SST and C0 to C7, and the memory cells C8 to C15 of the second vertical memory string C8 to C15 and DST, vertically connected in the memory block 110MB, are each controlled by operating voltages applied to the stacked word lines WL0 to WL7 and the stacked word lines WL8 to WL15. The above word lines WL0 to WL15 are classified in a memory block unit.

The select lines DSL and SSL and the word lines WL0 to WL15 serve as the local lines of the memory block 110MB. For example, the source select line SSL and the word lines WL0 to WL7 may serve as local lines of the first vertical memory string, and the drain select line DSL and the word lines WL8 to WL15 may serve as local lines of the second vertical memory string. Gates PG of the pipe transistors PT may be commonly connected in the memory block 110MB.

Referring again to FIGS. 1 and 2A, the operation circuits 120 to 170 may be configured to perform a program loop, an erase loop, and a read operation on memory cells (for example, C00 to C0k) connected to the selected word line (for example, WL0). The program loop may include a program operation and a verification operation, and the erase loop may include an erase operation and a verification operation.

The operation circuits 120 to 170 may perform the program loop with an increment step pulse program (ISPP) method. The operation circuits 120 to 170 may repeatedly perform the program operation and the verification operation until all of the threshold voltages of the memory cells C00 to C0k, connected to the selected word line (for example, WL0), reach a target level. The operation circuits 120 to 170 may repeatedly perform the program operation for storing data and the verification operation for checking the data storage until external input data is determined to have been stored in the memory cells C00 to C0k of the selected word line (for example, WL0).

The operation circuits 120 to 170 may increase a program voltage Vpgm applied to the selected word line by a determined step voltage whenever the program operation is repeatedly performed. The operation circuits 120 to 170 may apply the program voltage Vpgm increased from a program voltage, which was used in the previous program operation, by the step voltage, to the selected word line (for example, WL0) when the operation circuits 120 to 170 perform the program operation.

The operation circuits 120 to 170 may be configured to perform the program verification operation using a plurality of program verifying voltages different from each other. For example, when 2-bit data is stored in each unit cell, the program verification operation may be performed using three verifying voltages. When 3-bit data is stored in each unit cell, the program verification operation may be performed using seven verifying voltages.

The erase loop may be performed in substantially the same way as the program loop. The operation circuits 120 to 170 may increase an erase voltage Verase applied to a bulk (a substrate or a well-area) by a determined step voltage whenever the erase operation is repeatedly performed.

In order to perform the program loop, the erase loop, and the read operation, the operation circuits 120 to 170 may be configured to selectively output the operating voltages Verase, Vverify, Vpass, Vpgm, Vread, Vpass, Vdsl, Vssl, Vsl, and Vpg to the local lines SSL, WL0 to WLn, and DSL and the common source line SL of the selected memory block, and control precharge/discharge of the bit lines BLe and BLo or detect a current flow of the bit lines BLe and BLo. For example, the erase voltage Verase is applied in the erase operation to the substrate or bulk (not illustrated) in which the memory cells are formed. For example, the program voltage Vpgm is applied in the program operation to the selected word line, the read voltage Vread is applied in the read operation to the selected word line, and the verifying voltage Vverify is applied in the verification operation to the selected word line. The pass voltage Vpass is applied from the selected word line to the unselected word lines in the program operation, the read operation, or the verification operation. The drain select voltage Vdsl is applied to the drain select line DSL, the source select voltage Vssl is applied to the source select line SSL, and the source voltage Vsl is applied to the common source line SL. When the memory block is formed in the structure disclosed in FIG. 3C, the pipe gate voltage Vpg is applied to the pipe gate PG.

In a NAND flash memory device, the operation circuits may include a control circuit 120, a voltage supply circuit 130, a read/write circuit 140, a column select circuit 150, an input/output circuit 160, and a pass/fail check circuit 170. Each of the above circuits will be explained below as follows.

The control circuit 120 outputs a voltage control signal CMDv to control the voltage supply circuit 130 so that the voltage supply circuit 130 generates desired levels of operating voltages Verase, Vpgm, Vread, Vverify, Vpass, Vdsl, Vssl, Vsl, and Vpg, which perform the program loop, the erase loop, and the read operation in response to a command signal CMD input from the outside through the input/output circuit 160. The control circuit 120 outputs control signals CMDpb to control read/write circuits (or page buffers) PB included in the read/write circuit group 140 to perform the program loop, the erase loop, and the read operation. The control circuit 120 outputs a column address signal CADD and a row address signal RADD in response to an address signal ADD input to the control circuit 120.

The voltage supply circuit 130 generates the operating voltages Verase, Vpgm, Vread, Vverify, Vpass, Vdsl, Vssl, Vsl, and Vpg required for the program loop, the erase loop, and the read operation on the memory cells in response to the voltage control signal CMDv of the control circuit 120. The voltage supply circuit 130 outputs the operating voltages to the local lines SSL, WL0 to WLn, and DSL and the common source line SL in the selected memory block in response to the row address signal RADD of the control circuit 120.

The voltage supply circuit 130 may include a voltage generation circuit 131 and a row decoder 133. The voltage generation circuit 131 generates the operating voltages Verase, Vpgm, Vread, Vverify, Vpass, Vdsl, Vssl, Vsl, and Vpg in response to the voltage control signal CMDv of the control circuit 120, and the row decoder 133 transfers the operating voltages to the local lines SSL, WL0 to WLn, and DSL and the common source line SL in the selected memory block among the memory blocks 110MB in response to the row address signal RADD of the control signal 120. The verifying voltages Vpv1 to Vpv3 which will be explained below may be included in the verifying voltage Vverify output from the voltage supply circuit 130.

The read/write circuit group 140 may include a plurality of read/write circuits (for example, page buffers) PB respectively connected to the memory array 110 through the bit lines BLe and BLo. For example, the read/write circuits PB may be connected to the bit lines BLe and BLo, respectively. One read/write circuit PB may be connected to one bit line. The read/write circuits PB may be connected to a pair of the bit lines BLe and BLo, respectively.

In the program operation, the read/write circuits PB may selectively precharge the bit lines BLe and BLo based on the PB control signal CMDpb of the control circuit 120 and data DATA to be stored in the memory cells. For example, in the program operation, the read/write circuits PB may selectively apply a program inhibit voltage (for example, a power voltage) and a program allowance voltage (for example, a ground voltage) to the bit lines BLe and BLo. The threshold voltage of the memory cell connected to the precharged bit line (that is, the bit line to which the program inhibit voltage is applied) remains almost unchanged although the program voltage is applied to the memory cell. The threshold voltage of the memory cell connected to the discharged bit line (that is, the bit line to which the program allowance voltage is applied) may be increased by the program voltage.

In the verification operation or the read operation, based on the PB control signal CMDpb of the control circuit 120, the read/write circuits PB may precharge the bit lines BLe and BLo, and then detect a voltage variation or a current to latch data read from the memory cell.

Based on the data read from the memory cells in the verification operation (or the threshold voltages of the memory cells checked in the verification operation), the read/write circuits PB may output pass/fail signals, capable of determining a program pass/fail or an erase pass/fail of the memory cells, to the pass/fail check circuit 170. For these operations, the read/write circuits PB may include a plurality of latch circuits for temporarily storing data to be stored in the memory cells and for storing verification results of the memory cells.

The column select circuit 150 selects the read/write circuits PB included in the read/write circuit group 140 in response to the column address signal CADD output from the control circuit 120. The column select circuit 150 sequentially transfers data to be stored in the memory cells to the read/write circuits PB in response to the column address signal CADD. The column select circuit 150 sequentially selects the read/write circuits PB in response to the column address signal CADD so that data of the memory cells latched in the read/write circuits PB may be output to the outside by the read operation.

The input/output circuit 160 transfers the command signal CMD and the address signal ADD input from the outside to the control circuit 120. The input/output circuit 160 transfers the data DATA input from the outside to the column select circuit 150 in the program operation, or outputs data read from the memory cells to the outside in the read operation.

The pass/fail check circuit 170 may be configured to perform the verification operation to determine the program pass/fail, and then detect the amount of current varied based on check signals FF[0:k] output from the read/write circuits PB. The pass/fail check circuit 170 outputs a check result signal CHECKs to the control signal 120 based on the check signals FF[0: k].

The control circuit 120 may determine whether to perform the program operation or the erase operation again in response to the check result signal CHECKs.

The above-mentioned operation circuits 120 to 170 may be configured to apply a preprogram pulse to the selected word line, and then perform a main program loop including the main program operation and the program verification operation to store data in the memory cells. For example, the preprogram pulse may be higher than a first main program pulse applied to the selected word line when the main program operation of the program loop is first performed. The operation circuits 120 to 170 may apply at least two or more preprogram pulses to the selected word line before starting the main program loop. The operation circuits 120 to 170 may apply the preprogram pulse to the selected word line as a step-shaped single pulse. The preprogram pulse may be higher than the main program pulse applied to the selected word line when the memory cell, of which the threshold voltage is greater than the lowest program verifying voltage among the plurality of program verifying voltages, is detected.

Hereinafter, the method of operating the semiconductor device including the above-mentioned elements will be explained.

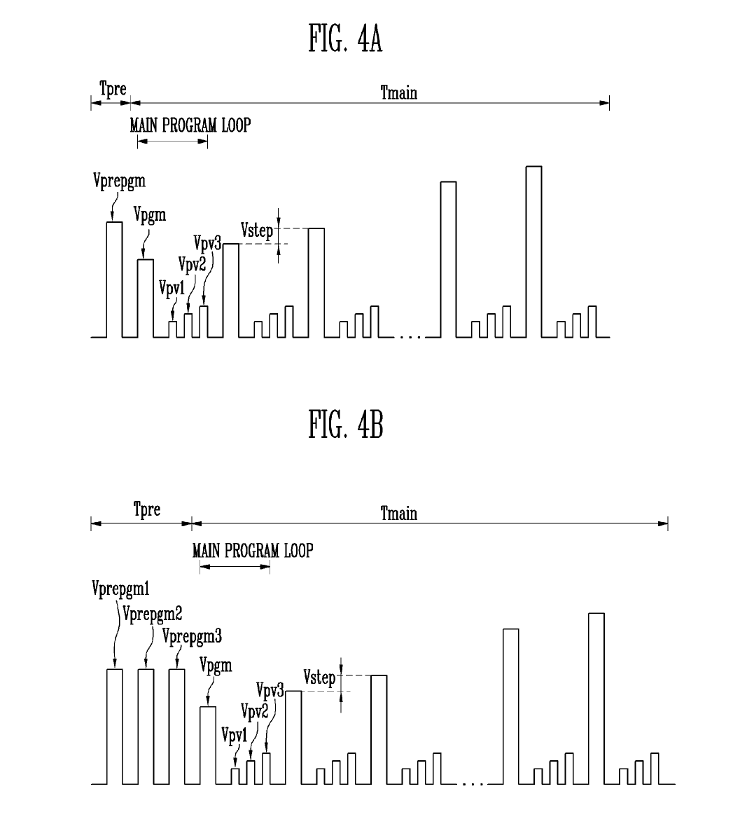

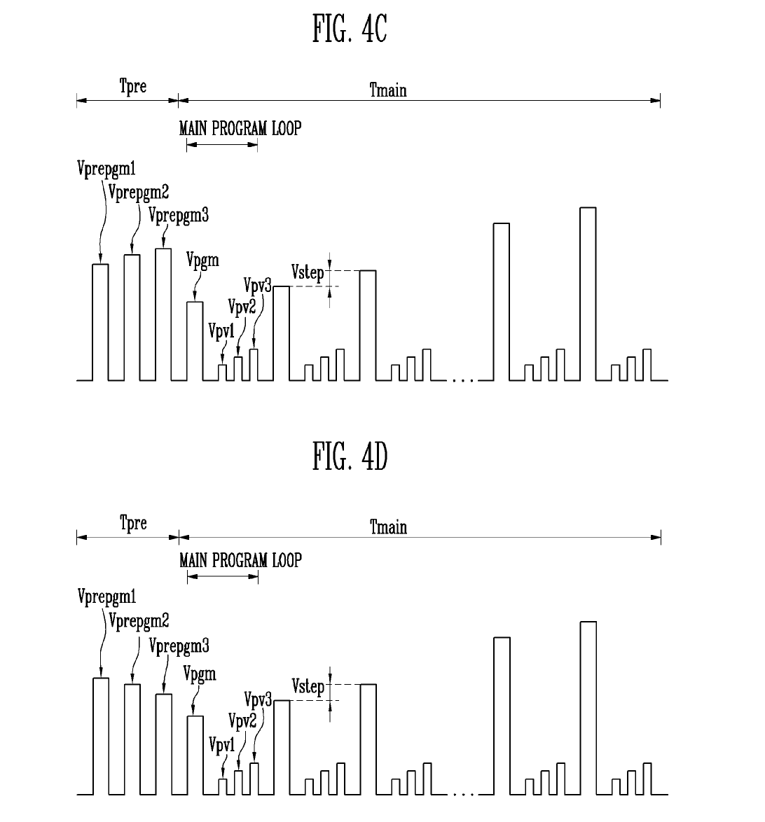

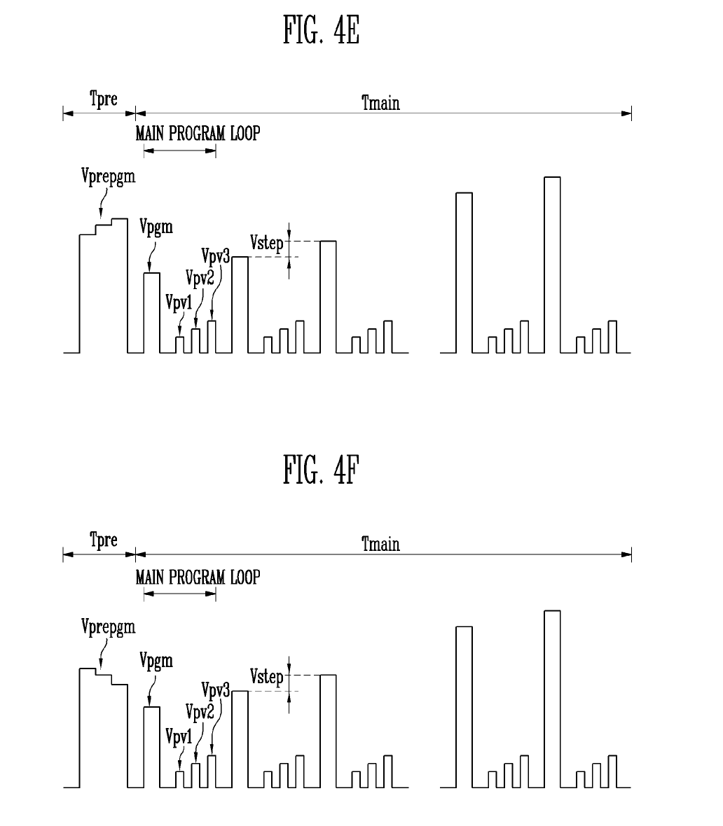

FIGS. 4A to 4F are waveforms illustrating a representation of an example of a method of operating a semiconductor device according to an embodiment.

Referring to FIGS. 1, 2A and 4A, the command signal CMD and the address signal ADD associated with the program operation are applied to the control circuit 120 through the input/output circuit 160, and the data DATA to be stored in the memory cells C00 to C0k of the selected word line (for example, WL0) is latched in the read/write circuit 140 through the input/output circuit 160 and the column select circuit 150.

In a first interval Tpre, the operation circuits 120 to 170 may apply the preprogram pulse Vprepgm to the selected word line before the operation circuits 120 to 170 performs the main program loop for storing the data DATA in the memory cells C00 to C0k.

The preprogram pulse Vprepgm may be higher than the first main program pulse Vpgm applied to the selected word line (for example, WL0) when the main program operation is first performed. The preprogram pulse Vprepgm may be higher than the main program pulse applied to the selected word line when the memory cell, of which the threshold voltage is greater than the lowest program verifying voltage among the plurality of program verifying voltages, is detected.

When the preprogram pulse Vprepgm is applied to the selected word line (for example, WL0), based on the data to be stored, the operation circuits 120 to 170 may apply the program inhibit voltage to the bit line of the memory cell required to maintain an erase state, and apply the program allowance voltage to the bit lines of the memory cells of which the threshold voltage is required to be increased to program levels.

After the preprogram pulse Vprepgm is applied to the selected word line (for example, WL0), in a second interval Tmain, the operation circuits 120 to 170 perform the main program loop. At first, for the program operation, the read/write circuit 140 selectively precharges the bit lines BLe and BLo based on the data to be stored in the memory cells C00 to C0k. The voltage supply circuit 130 applies the main program pulse Vpgm to the selected word line (for example, WL0) of the memory block 110MB, and applies the pass voltage Vpass to the unselected word lines. The main program pulse Vpgm applied to the selected word line (for example, WL0) in the main program operation which is first performed, is applied at a lower level than the preprogram pulse Vprepgm.

For the program verification operation, the program verifying voltages Vpv1, Vpv2 and Vpv3 may be sequentially applied to the selected word line (for example, WL0). When the memory cell of which the threshold voltage is lower than the target level (that is, the memory cell in which data is not stored) is detected, the operating circuits 120 to 170 increase the main program pulse Vpgm by the step voltage Vstep, and then repeatedly perform the main program loop. The operating circuits 120 to 170 repeatedly perform the main program loop until the operating circuits 120 to 170 determines that the data is stored in the memory cells C00 to C0k as desired.

According to the operations explained above, after the preprogram pulse Vprepgm is applied to the first selected word line (for example, WL0), the main program loop is performed without the verification operation. Due to this reason, when the operation for storing data in the memory cells C00 to C0k begins, the preprogram pulse Vprepgm and the main program pulse Vpgm are sequentially applied. Then, since only the main program loop is performed, the preprogram pulse Vprepgm is not applied any more, and only the main program pulse Vpgm is applied. That is, after the program verification operation is performed, the preprogram pulse Vprepgm is not applied, and the main program pulse Vpgm is applied to the selected word line (for example, WL0) in order to perform the main program operation.

Referring to FIGS. 1, 2A and 4B, in the first interval Tpre, the operation circuits 120 to 170 may apply at least two or more preprogram pulses Vprepgm1 to Vprepgm3 to the selected word line (for example, WL0). The operation circuits 120 to 170 may apply the preprogram pulses Vprepgm1 to Vprepgm3 at the same level to the selected word line. Then, in the second interval Tmain, the main program loop may be performed according to the above-mentioned method.

Referring to FIGS. 1, 2A and 4C, in the first interval Tpre, the operation circuits 120 to 170 may apply at least two or more preprogram pulses Vprepgm1 to Vprepgm3 to the selected word line (for example, WL0) at different levels. For example, the operation circuits 120 to 170 may apply the preprogram pulses Vprepgm1 to Vprepgm3 at gradually increasing levels to the selected word line. Then, in the second interval Tmain, the main program loop may be performed according to the above-mentioned method.

Referring to FIGS. 1, 2A and 4D, in the first interval Tpre, the operation circuits 120 to 170 may apply at least two or more preprogram pulses Vprepgm1 to Vprepgm3 to the selected word line (for example, WL0) at different levels. For example, the operation circuits 120 to 170 may apply the preprogram pulses Vprepgm1 to Vprepgm3 at gradually decreasing levels to the selected word line. Then, in the second interval Tmain, the main program loop may be performed according to the above-mentioned method.

Referring to FIGS. 1, 2A and 4E, in the first interval Tpre, the operation circuits 120 to 170 may apply the preprogram pulse Vprepgm with a single pulse of which the level varies in a step shape, to the selected word line (for example, WL0). For example, the operation circuits 120 to 170 may apply the preprogram pulse Vprepgm to the selected word line (for example, WL0) as the single pulse in an increasing step shape. Then, in the second interval Tmain, the main program loop may be performed according to the above-mentioned method.

Referring to FIGS. 1, 2A and 4F, in the first interval Tpre, the operation circuits 120 to 170 may apply the preprogram pulse Vprepgm to the selected word line (for example, WL0) as a single pulse in a decreasing step shape. Then, in the second interval Tmain, the main program loop may be performed according to the above-mentioned method.

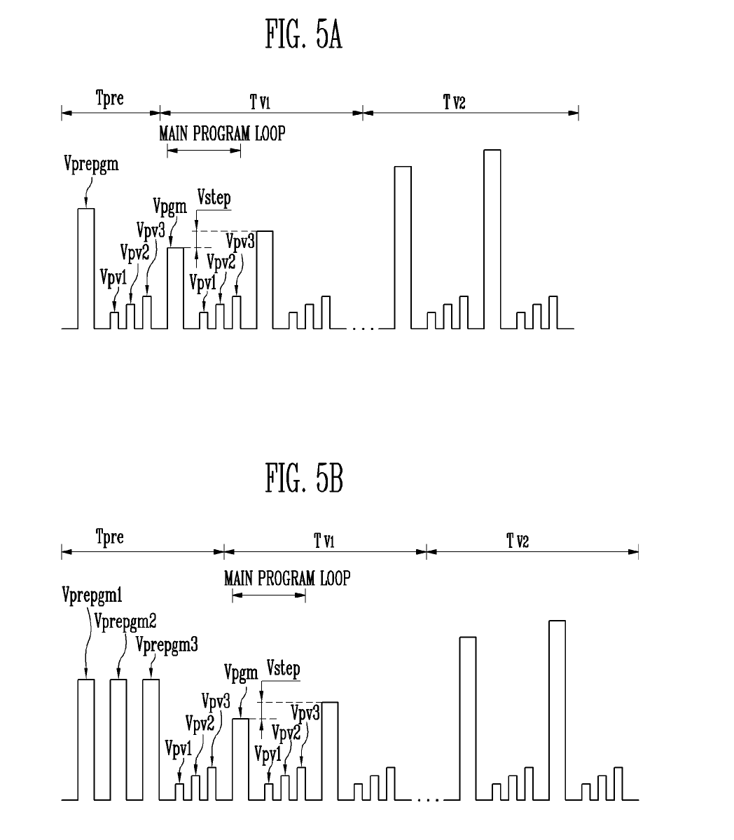

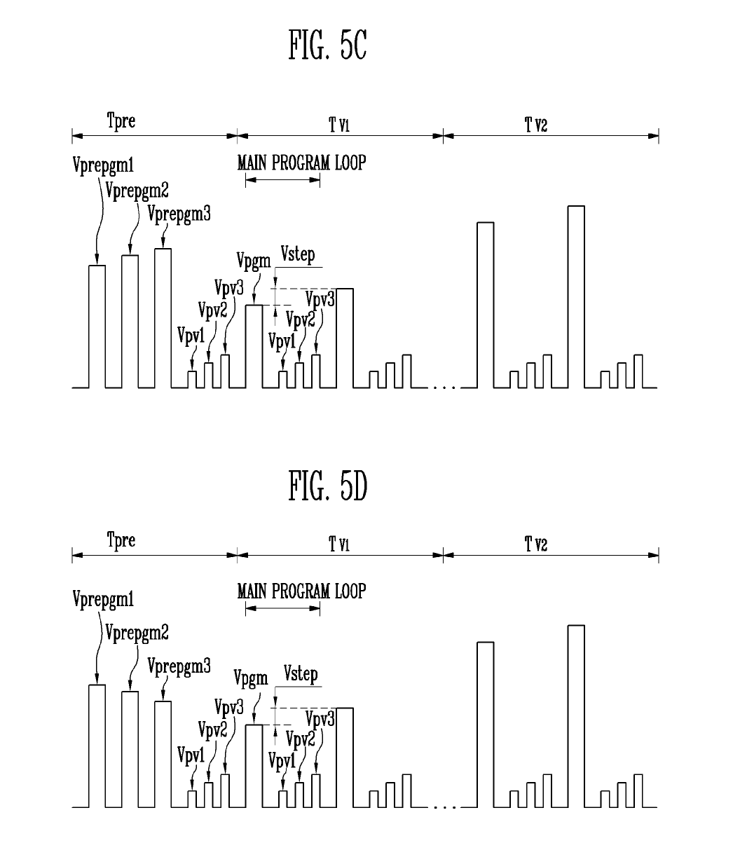

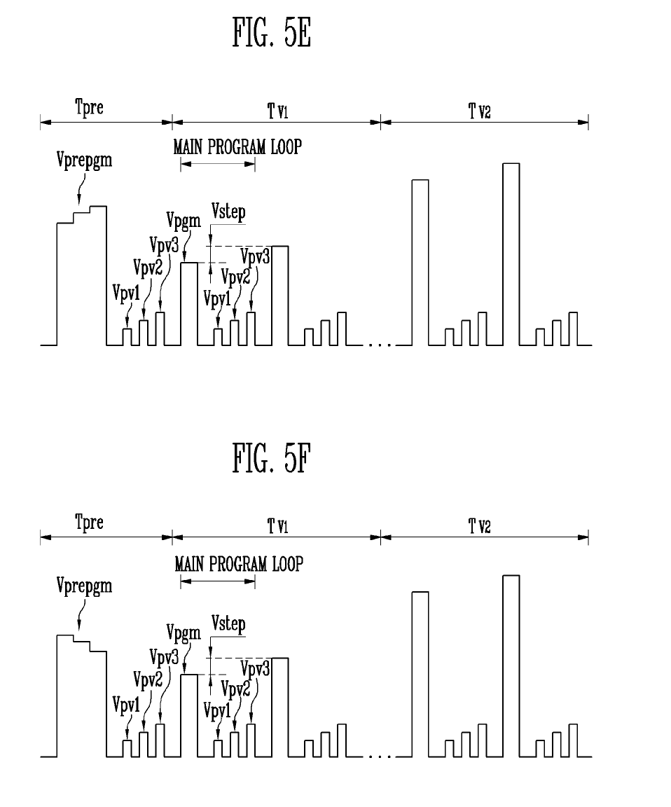

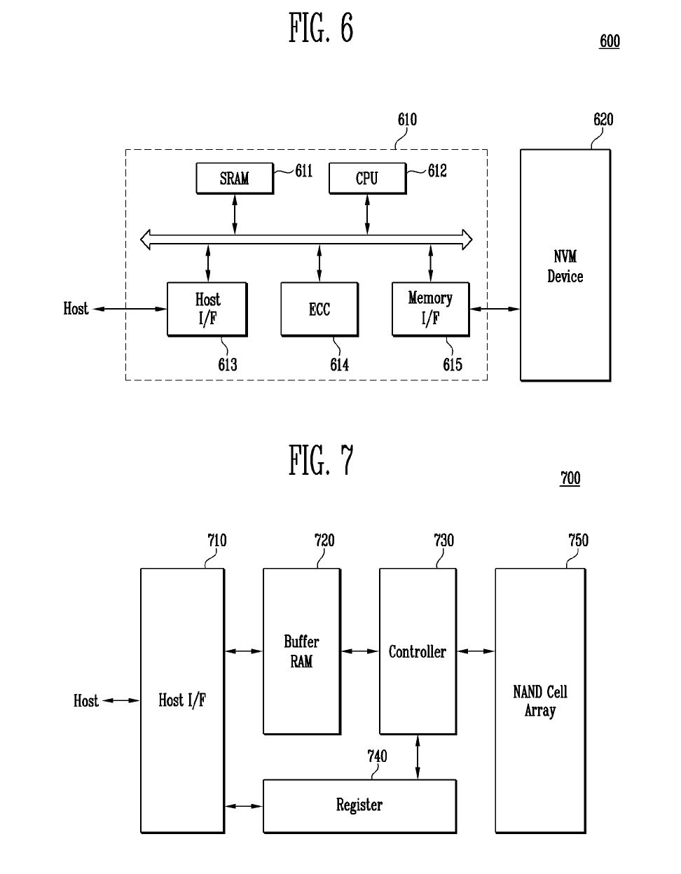

FIGS. 5A to 5F are waveforms illustrating a representation of an example of a method of operating a semiconductor device according to an embodiment.

Referring to FIGS. 5A to 5F, in the first interval Tpre, the operation circuits 120 to 170 apply the preprogram pulse Vprepgm or the preprogram pulses Vprepgm1 to Vprepgm3 in the same way as the preprogram pulse Vprepgm or the preprogram pulses Vprepgm1 to Vprepgm3 illustrated in FIGS. 4A to 4F. The operation circuits 120 to 170 perform the verification operation using different verifying voltages Vpv1 to Vpv3. That is, in the first interval Tpre, the operation circuits 120 to 170 perform one preprogram loop.

Then, in the second interval Tmain, the operation circuits 120 to 170 perform the main program loops according to the above-mentioned methods. When the operation circuits 120 to 170 perform the main program loops, the program inhibit voltage is applied to the bit lines of the memory cells of which the threshold voltages have been increased higher than the target level by the preprogram loop. That is, the memory cells, of which the threshold voltages has been increased higher than the target level by the preprogram loop, are not programmed any more in the main program loop.

By performing the program loop for storing data in the memory cells according to the above-mentioned method, the operating time and the operation characteristics may be improved.

FIG. 6 is a block diagram illustrating a representation of an example of a memory system according to an embodiment.

Referring to FIG. 6, a memory system 600 according to an embodiment may include a nonvolatile memory (NVM) device 620 and a memory controller 610.

The NVM device 620 may correspond to the semiconductor device illustrated in FIG. 1, and the memory array and the operating circuits may be connected to the semiconductor device as explained with relation to FIG. 1. The memory controller 610 may be configured to control the NVM device 620. The NVM device 620 may be combined with the memory controller 610, and used for a memory card or a semiconductor disk device such as a solid state disk (SSD). An SRAM 611 is used as an operational memory of a central processing unit (CPU) 612. A host interface 613 includes a data exchange protocol of a host Host connected to the memory system 600. An error correcting block (ECC) 614 detects and corrects an error in the data read from a cell area of the NVM device 620. A memory interface 615 interfaces with the NVM device 620. The CPU 612 performs overall control operations for data exchange of the memory controller 610.

Although not illustrated in FIG. 6, a person skilled in the art will understand that the memory system 600 according to the embodiments may further include a ROM (not illustrated) configured to store code data for interfacing with the host Host, and/or the like. The NVM device 620 may be provided as a multi-chip package having a plurality of flash memory chips. The memory system 600 according to the various embodiments may be provided as a highly reliable storage medium having improved operation characteristics. In particular, the flash memory device according to the embodiments may be included in a memory system such as a semiconductor disk device (an SSD). In these examples, the memory controller 610 may be configured to communicate with the outside (for example, the host Host) through at least one of various interface protocols such as a USB, an MMC, a PCI-E, an SATA, a PATA, an SCSI, an ESDI, an IDE, etc.

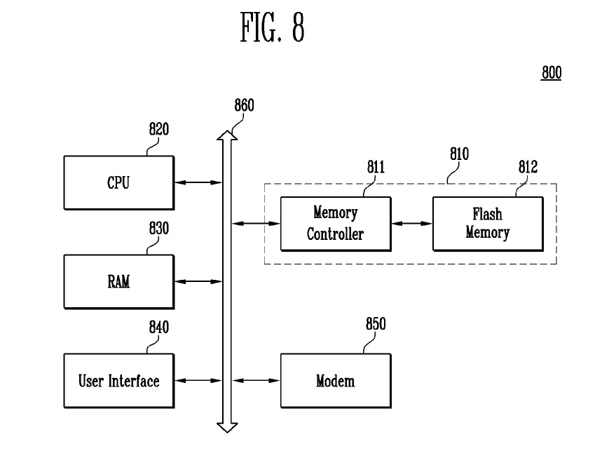

FIG. 7 is a block diagram illustrating a representation of an example of a fusion memory device or a fusion memory system configured to perform a program operation according to the above-mentioned embodiments. For example, technical characteristics of the embodiments may be applied to an OneNAND flash memory device 700 as a fusion memory device.

The OneNAND flash memory device 700 may include a host interface 710 configured to exchange overall information with devices using different protocols, a buffer RAM 720 which includes a code configured to drive the memory device or temporarily store data, and a controller 730 configured to control a read operation. The OneNAND flash memory device 700 may include a program operation, and all states in response to a control signal and a command provided from the outside, a register 740 configured to store data such as the command, and an address, and a configuration for defining a system operation environment inside the memory device, and/or the like. The OneNAND flash memory device 700 may include a NAND flash cell array 750 including an operation circuit having a nonvolatile memory cell and a page buffer. The OneNAND flash memory device 700 programs data in a general method in response to a write request from the host Host.

FIG. 8 is a block diagram illustrating a representation of an example of a computing system including a flash memory device 812 according to an embodiment.

The computing system 800 according to the embodiments may include a CPU 820, a RAM 830, a user interface 840, a modem 850 such as a baseband chipset, and a memory system 810. The CPU 820, a RAM 830, a user interface 840, a modem 850, and memory system 810 may all be electrically connected to a system bus 860. When the computing system 800 is a mobile device, a battery (not illustrated) configured to supply an operating voltage to the computing system 900 may be additionally provided. Although not illustrated in FIG. 8, a person skilled in the art will understand that, in the computing system 800 according to the embodiments, an application chipset, a camera image processor (CIS), a mobile DRAM, and/or the like may be further provided. The memory system 810, for example, may be included in a solid state drive/disk (SSD) using the nonvolatile memory device described in FIG. 1 so as to store data, or the memory system 810 may be provided to a fusion flash memory (for example, the OneNAND flash memory).

Although the application has been described with reference to the above embodiments, it will be apparent to those skilled in the art that various modifications can be made to the above-described examples of embodiments without departing from the spirit or scope of the application.

What is claimed is:

1. A semiconductor device comprising:
a memory block including memory cells, the memory cells connected to a word line; and
an operation circuit configured to apply a preprogram pulse to the word line, and to perform a main program loop including a main program operation and a program verification operation to store data in the memory cells connected to the word line,
wherein the preprogram pulse has a higher voltage level than a first main program pulse applied to the word line when the main program operation is first performed.

2. The semiconductor device of claim 1, wherein after the program verification operation is performed, a main program pulse is applied to the word line to perform the main program operation.

3. The semiconductor device of claim 1, wherein the preprogram pulse has a higher voltage level than a main program pulse applied to the word line when a memory cell having a threshold voltage is higher than a lowest program verifying voltage among a plurality of program verifying voltages is detected.

4. The semiconductor device of claim 3, wherein when the memory cell having a threshold voltage lower than a target level is detected, the operation circuit increases the main program pulse by a step voltage.

5. The semiconductor device of claim 1, wherein the operation circuit is configured to apply at least two or more preprogram pulses to the word line prior to performing the main program loop.

6. The semiconductor device of claim 5, wherein the operation circuit is configured to apply the preprogram pulses at substantially the same voltage levels to the word line.

7. The semiconductor device of claim 5, wherein the operation circuit is configured to apply the preprogram pulses at increasing voltage levels to the word line.

8. The semiconductor device of claim 5, wherein the operation circuit is configured to apply the preprogram pulses at decreasing voltage levels to the word line.

9. The semiconductor device of claim 1, wherein the operation circuit is configured to apply the preprogram pulse as a single pulse including an increasing step shape.

10. The semiconductor device of claim 1, wherein the operation circuit is configured to apply the preprogram pulse as a single pulse including a decreasing step shape.

11. A semiconductor device comprising:
a memory block including memory cells, the memory cells connected to a word line; and
an operation circuit configured to perform a preprogram operation and a preprogram verification operation, and to perform a main program loop including a main program operation and a program verification operation to store data in the memory cells connected to the word line,
wherein the preprogram pulse of the preprogram operation has a higher voltage level than a first main program pulse of the main program loop applied to the word line.

12. The semiconductor device of claim 11, wherein the main program loop is repeatedly performed after the preprogram verification operation is performed.

13. The semiconductor device of claim 11, wherein the preprogram pulse has a higher voltage level than a main program pulse applied to the word line when a memory cell having a threshold voltage is higher than a lowest program verifying voltage among a plurality of program verifying voltages is detected.

14. The semiconductor device of claim 13, wherein when the memory cell having a threshold voltage lower than a target level is detected, the operation circuit increases the main program pulse by a step voltage.

15. The semiconductor device of claim 11, wherein the operation circuit is configured to apply at least two or more preprogram pulses to the word line to perform the preprogram operation.

16. The semiconductor device of claim 15, wherein the operation circuit is configured to apply the preprogram pulses at substantially the same level to the word line.

17. The semiconductor device of claim 15, wherein the operation circuit is configured to apply the preprogram pulses at increasing voltage levels to the word line.

18. The semiconductor device of claim 15, wherein the operation circuit is configured to apply the preprogram pulses at decreasing voltage levels to the word line.

19. The semiconductor device of claim 11, wherein the operation circuit is configured to apply the preprogram pulse as a single pulse including an increasing step shape to perform the preprogram operation.

20. The semiconductor device of claim 11, wherein the operation circuit is configured to apply the preprogram pulse as a single pulse including a decreasing step shape to perform the preprogram operation.
